(19) United States
(12) Patent Application Publication
(10) Pub. No.: US 2003/0235227 A1
(43) Pub. Date: Dec. 25, 2003

(54) Spot-size-converted laser for unisolated transmission

(76) Inventors: Naresh Chand, Warren, NJ (US); Julie Eng, Upper Macungie Township, PA (US); Martin Christian Fischer, Bridgewater, NJ (US); Philip Anthony Kiely, Clinton, NJ (US); David J. Klotzkin, Emmaus, PA (US); Keisuke Kojima, Bridgewater, NJ (US); Genji Tohmon, Allentown, PA (US); Yan Xu, Macungie, PA (US)

Correspondence Address: CHRISTIE, PARKER & HALE, LLP, 350 WEST COLORADO BOULEVARD, SUITE 500, PASADENA, CA, 91105, US

(21) Appl. No.: 10/174,805

(22) Filed: Jun. 19, 2002

(51) Int. Cl. H01S 5/00

(52) U.S. Cl. 372/50

(57) ABSTRACT

A transmit optical subassembly (TOSA) includes a spot-size-converted (SSC) semiconductor laser coupled to an optical fiber without a lens or isolator. The spot-size-converted semiconductor laser includes an active region and an expander region that expands the spot size of the laser while maintaining efficient active laser performance. The SSC laser is coupled to a submount and passively aligned to an optical fiber positioned within a V-shaped groove formed within the submount. The SSC laser includes a narrow far field advantageous for providing a high coupling efficiency and high quality data transmission. The SSC laser is resistant to back reflection and produces a 1.3 or 1.55 micron optical wavelength and a data rate ranging from 1 to 10 Gbps. The TOSA provides high coupled power due to narrow far field, with potential extra reflection resistance due to absorption and mode transfer losses in coupling reflections through the expander back into the active region. The TOSA meets industry specifications (SDH/SONET) for 15 km transmission and has a maximum optical path penalty of less than 1 dB at a bit error ratio of 10⁻¹⁰ for up to −14 dB back reflection.

### FIELD OF THE INVENTION

The present invention relates most generally to optical subassemblies. More particularly, the present invention relates to a TOSA (transmit optical subassembly) including a spot-size-converted laser passively aligned to an optical transmission medium for unisolated transmission.

### BACKGROUND OF THE INVENTION

The trend in the optoelectronics industry is towards integrating more functionality into smaller packages. As the optoelectronics industry matures and expands from traditional telecommunications into newer areas like data communications, components are also evolving to meet more compact, integrated, and cost-sensitive requirements. One major step towards cost-effective optoelectronics is the development of lasers such as spot-size-converted (SSC) lasers which have high alignment tolerances and can be passively aligned to an optical transmission medium to reduce or eliminate alignment time and achieve a cost-savings. In a completed packaged transceiver or transponder, it is highly desirable to include the laser as a bare chip passively coupled to an optical transmission medium, rather than as a separately packaged pigtailed laser device. In addition to eliminating the time for active alignment, this eliminates additional packaging costs, and removes many of the high-speed limitations associated with the laser package. Consistent with the low cost, highly integrated approach, the lasers should desirably operate uncooled, requiring the laser to have good high temperature performance and excellent aging characteristics.

Such applications require a laser that can couple a large fraction of its emitted light into an optical transmission medium without optics. To achieve an optical coupling comparable to traditional packaged devices using passive alignment, it is essential that the device have a narrow far field pattern of the outgoing light. Typical buried heterostructure (BH) lasers with a 30×30 degree far fields can couple at most 10-15% of their light into a flat cleaved fiber. Spot size converted (SSC) lasers provide a reduced far field enabling passive alignment thereby reducing packaging costs. Understandably, the alignment tolerances, defined as the maximum excursions of the fiber that can still meet a minimum coupled power specification, are much greater for a narrow far field device.

To produce such an acceptably narrow far field, a relatively large spot size is required. A trade-off, however, is that large spot sizes are not consistent with good active laser performance.

Moreover, If optical isolators and associated lenses are required to couple the SSC laser to the optical transmission medium, the cost savings associated with passive alignment are lost due to the cost of these additional components and the need to align them. As such, unisolated transmission is desirable to reduce costs.

Another important aspect in the high speed optical communications industry is the need to produce lasers that provide optical signals having high data rates (bit rates of 1 Gbps and greater) to increase transmission capacity. As such the lasers used in the above-described integrated subassemblies, should desirably have a performance equivalent to standard BH 2.5 Gbps directly modulated lasers. Unisolated transmission is difficult, however at these high bit rates, because high reflection creates power penalties at such high bit rates.

It would therefore be advantageous to provide a high slope efficiency laser that can provide sufficient optical power into an optical transmission medium at a reduced coupling efficiency and without a lens or isolator. More particularly, it would be desirable to provide a spot size converted laser that produces an optical data signal along an optical transmission medium that satisfies industry standard specifications for acceptably low bit error rates, high speed, and sufficient resistance to external optical reflection, for suitably long transmission distances. Similarly, it would be advantageous to provide an optical subassembly including such a laser coupled to an optical transmission medium by passive alignment.

### SUMMARY OF THE INVENTION

Accordingly, the present invention is directed to a laser and an optical subassembly (OSA) including the laser directly coupled to an optical transmission medium and producing an optical signal that provides high data rates, low bit error rates, and complies with United States and international industry standard specifications for data transmission. For purposes of the present invention, directly coupled means that there are no intervening components interposed between the laser and the optical transmission medium.

In one embodiment, the present invention provides a TOSA (transmit optical subassembly) that includes a spot-size-converted semiconductor laser directly coupled to an optical transmission medium without a lens or isolator, and provides an optical data signal having a bit error rate no greater than 10⁻¹⁰ and at a data speed of 1-10 Gbps.

According to another exemplary embodiment, the present invention provides a TOSA including a spot-size-converted semiconductor laser coupled to an optical transmission medium without a lens or isolator and which provides an optical data signal having a maximum 1 dB optical path power penalty with a maximum −19 dB back reflection.

According to another exemplary embodiment, the present invention provides a TOSA including a spot-size-converted semiconductor laser coupled to an optical transmission medium without a lens or isolator and which provides an optical data signal that satisfies at least one of ITU-T SDH STM-16 and STM-48 standard specifications and SONET OC-48 and OC-192 standard specifications for data transmission.

According to another exemplary embodiment, the present invention provides a TOSA with a spot-size-converted semiconductor laser affixed to a submount. The submount includes a groove which receives and thereby passively aligns an optical transmission medium to the laser.

According to another exemplary embodiment, the present invention provides a method for transmitting an optical signal. The method includes providing a spot-size-converted semiconductor laser coupled to a submount that includes a groove for passively aligning an optical transmission medium to the laser, and also providing an optical fiber having an end capable of being received within the groove. The method further includes passively aligning the optical fiber to the laser without a lens or isolator by positioning the end of the optical fiber in the groove such that the laser provides an optical data signal along the optical fiber having a bit error rate less than 10⁻¹⁰ and a data rate of 1-10 Gbps, and then causing the laser to emit light.

According to another exemplary embodiment, the present invention provides a method for providing a spot-size-converted semiconductor laser coupled to a submount that includes a groove for passively aligning an optical transmission medium to the laser and providing an optical fiber having an end capable of being received within the groove. The optical fiber is then passively aligned to the laser by positioning the optical transmission medium in the groove. The laser is then caused to emit light producing a coupling efficiency of at least 25%.

It is to be understood that both the foregoing general description and the following detailed description are exemplary and explanatory of the claimed invention and are not presented by way of limitation.

### BRIEF DESCRIPTION OF THE DRAWING

The present invention is best understood from the following detailed description when read in conjunction with the accompanying drawing. It is emphasized that, according to common practice, the various features of the drawing are not to scale. On the contrary, the dimensions of the various features are arbitrarily expanded or reduced for clarity. Like numerals denote like features throughout the specification and drawing. Included in the drawing are the following figures:

FIG. 1 is a cross-sectional view of an exemplary spot-size-converted laser of the present invention;

FIG. 2 is a plan view of the exemplary spot-size-converted laser of the present invention;

FIG. 3 is a graph showing the far field of the spot-size-converted laser of the present invention;

FIG. 4 is a perspective view of the spot-size-converted laser of the present invention formed on a submount and passively aligned to an optical fiber;

FIG. 5 is a graph showing reflection tolerance versus coupling efficiency;

FIG. 6 is a graph showing bit error rate versus received power for various reflection levels for 5 meter transmission and including a 10% coupling efficiency; and

FIG. 7 is a graph showing bit error rate versus received power for various reflection levels for a 16.1 km transmission and a 10% coupling efficiency.

### DETAILED DESCRIPTION OF THE INVENTION

To provide a high quality optical data signal transmission, a laser advantageously includes a narrow far field. The advantageous utilization of a narrow far field exiting from a laser implies a large spot-size such as four micron full width half maximum, inside the device cavity. Such a large spot size is not consistent with good active laser performance. Accordingly, the present invention provides a spot-size-converted semiconductor laser that includes an active region with a relatively small spot size and a mode expander region which enlarges the spot size. This combination of an active region with a relatively small spot size and an expander section with an enlarged spot size gives both good confinement to the active region and a narrow far field such as required for a high coupling efficiency and high quality data transmission.

The present invention provides such a spot-size-converted laser that includes a narrow far field, is capable of high coupling efficiency of the light directly into an optical fiber without an isolator or lens and has the ability to transmit without error floors or excessive power penalties. The laser of the present invention can therefore be packaged in an integrated transmitter or transceiver whereby the laser is mounted on a submount inside the transmitter, transceiver or transponder along with other electronics, uncooled, and directly coupled and passively aligned to an optical fiber or the like. The spot-size-converted laser so coupled to an optical fiber and passively aligned without a lens or isolator, provides sufficient resistance to external optical reflection to enable transmission up to 15 kilometers and greater, at reduced optical coupling efficiencies and is suitable for telecommunications and data communications.

Transmitter optical subassemblies, transceiver optical subassemblies and transponders are hereinafter referred to collectively as TOSAs. Transceiver optical subassemblies include receive components in addition to transmit components and transponders include transceiver capabilities along with electrical mutiplexing and demultiplexing components in the same package. In one embodiment, the optical data signal provided by the laser in the TOSA of the present invention can withstand −14 dB reflection and remain within the ITU-T specified 1 dB optical path power penalty at a bit error rate of 10⁻¹⁰, thereby meeting and surpassing ITU-T SDH G.957 STM-16 S-16.1 standards for 15 km transmission which allows a maximum reflectance of −19 dB. The ITU-T specified optical path power penalty is a power penalty due to dispersion, reflection, and other sources. Bit error rate (BER) may also be referred to as the bit error ratio and the terms may therefore be used interchangeably, hereinafter. The TOSA includes a data signal having a data rate as high as 10 Gbps, and generally within the range of 1-2.5 Gbps.

The TOSA including the passively aligned, spot size converted laser of the present invention, provides an optical output in the form of a data signal that complies with ITU-T Synchronous Digital Hierarchy (SDH), Synchronous Transport Module (STM) specifications STM-16 and STM-48 for 2.5 Gbps and 10 Gbps transmissions, respectively, in various embodiments. In other exemplary embodiments, the optical output data signal of the SSC laser/TOSA of the present invention also complies with SONET (Synchronous Optical Network) standard specifications OC-48 and OC-192 for 2.5 Gbps and 10 Gbps transmission, respectively. Moreover, in other exemplary embodiments, the optical output/data signal of the present invention may comply with Fiber Channel (ANSI X3T11), Gigabit Ethernet (IEEE 802.3z 1000BASE-LX) and 10 Gigabit Ethernet standards for 1.3 μm lasers (IEEE 802.ae 10GBASE-L) and for 1.55 μm lasers (IEEE 802.ae 10GBASE-E).

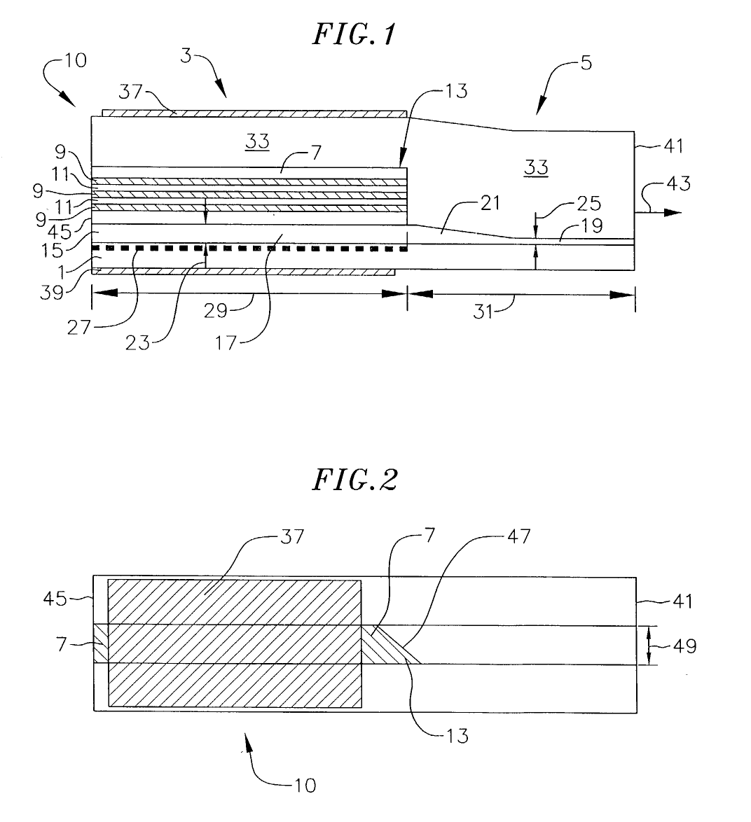

FIG. 1 is a cross-sectional view showing an exemplary spot-size-converted (SSC) semiconductor laser of the present invention. SSC laser 10 is formed on substrate 1. SSC laser 10 includes opposed ends or facets 41 and 45. SSC laser 10 includes active region 3 and expander region 5. In one exemplary embodiment, active region 3 includes a strained multi-quantum well (MQW) InGaAsP conventional buried-heterostructure (BH) laser operating at 1.3 μm. SSC laser 10 may be a Fabry-Perot laser or it may be a distributed feedback (DFB) laser including grating structure 27 formed within substrate 1. Substrate 1 may be formed of Si, GaAs, InP or other suitable materials. In the Fabry-Perot embodiment, grating structure 27 is not present. Grating structure 27 may be formed using holographic or other methods and is a repeating sequence of a material formed at regular intervals within substrate 1 to tune the laser to a desired output wavelength. In one exemplary embodiment, grating structure 27 may be a periodic loss or gain structure. MQW 7 includes a sequence of alternating layers 9 and 11 and, in an exemplary embodiment, forms a mesa structure which includes a beveled edge 13. Alternating layers 9 and 11 are chosen to have different refractive indices and in one embodiment may be a repeating sequence of InGaAsP with a 70:30 arsenic to phosphorus ratio, and InGaAsP with a 60:40 arsenic to phosphorus ratio. According to other embodiments, other compositions may be used. According to still other exemplary embodiments, other semiconductor heterostructure families such as InGaAlAs may be used. Layers 9 and 11 of MQW 7, as well as waveguide 15 and cladding layer 33, may each be formed using MOCVD (metalorganic chemical vapor deposition) or other suitable techniques.

Waveguide 15 extends under both active region 3 and expander region 5 of SSC laser 10. In an exemplary embodiment, waveguide 15 may be a quaternary InGaAsP material surrounded by InP cladding material 33 in expander region 5. In one particularly advantageous embodiment, waveguide 15 may be an InGaAsP layer with a characteristic luminescence of 1.17 microns and zero strain, but other compositions may be used in other exemplary embodiments. The mode transfer of light generated in MQW 7 of active region 3 to underlying waveguide 15 is accomplished through a lateral taper etch removal of the active MQW layers. This lateral taper etch provides beveled end 13 as will be shown more clearly in FIG. 2. Underlying waveguide 15 may be grown using selective area growth (SAG) in order to produce a relatively thick waveguide portion 17 at the mode transition region of active region 3 while maintaining a relatively thin waveguide portion 19 in expander region 5 to achieve a large spot size and narrow far field. It can be seen that thickness 23 of relatively thick waveguide portion 17 in the mode transition region, is greater than corresponding thickness 25 of relatively thin waveguide portion 19 in the expander region. Waveguide 15 also includes taper 21 between relatively thick waveguide portion 17 and relatively thin waveguide portion 19. Cladding layer 33 may be formed of InP in an exemplary embodiment.

SSC laser 10 includes active region length 29, which may vary from 200 to 400 microns in various exemplary embodiments, and may be about 300 microns in a particular embodiment. Expander region length 31 may vary from 150 to 300 microns in various exemplary embodiments. Such dimensions are intended to be exemplary only, and the described materials of formation are exemplary and not limiting of the various structures used for the present invention. Multiple lasers of the present invention may be formed simultaneously on a substrate, then cleaved into individual SSC lasers. Photolithographic and conventional wet and dry etching techniques may additionally or alternatively be used to size the individual SSC lasers. After the laser structure is formed, conductive contact layers are formed to provide electrical contact. In an exemplary embodiment, N-contact metal 39 may be formed on the bottom surface of substrate 1 and P-contact metal 37 may be formed over SSC laser 10. Conventional metalization and dry and/or wet etching techniques may be used. Conventional electronic circuitry may be coupled to N-contact metal 39 and P-contact metal 37 using conventional means and conventional means may be used to provide electrical power to SSC laser 10 and cause it to lase and emit light.

The materials that form the various layers and the thicknesses may be chosen to desirably produce a laser that emits light having various wavelengths such as 1.3 μm and 1.55 μm. In one exemplary embodiment, light having a median wavelength of about 1.3 μm (1290-1330 nm) may be used, where chromatic dispersion in a standard single mode optical fiber is minimal, but other embodiments may include light of various other wavelengths such as about 1.55 μm (1530-1565 nm), where optical fiber loss is small and erbium doped fiber amplifiers are used. SSC laser 10 includes opposed facets 45 and 41 and light is emitted from facet 41 along direction 43 in the illustrated embodiment. In an exemplary embodiment, facet 45 may be coated with a reflective material to enhance reflectivity within MQW 7 and facet 41 may be coated with an antireflective material to enhance transmission and reduce reflection back into the lasing chamber. In combination, such coatings provide a high slope efficiency laser capable of launching sufficient power into an optical transmission medium at a reduced coupling efficiency.

The spot size within active region 3 is relatively small to insure good active laser performance, and the spot size within expander region 5 is relatively large to provide a narrow far field. In an exemplary embodiment, spot size within active area 3 may be 1 μm and expanded to a spot size of 4 μm in expander region 5, but other absolute and relative spot sizes may be used in other exemplary embodiments depending on device application, materials and thicknesses of materials used to form SSC laser 10, optical coupling considerations and data transmission requirements. Various thicknesses may be used and various numbers of alternating layers 9 and 11 may be used to form MQW 7, as would be appreciated by one of ordinary skill in the art.

FIG. 2 is a plan, top view of SSC laser 10 shown in FIG. 1. FIG. 2 shows P-contact metal 37 formed over the top of SSC laser 10. The mesa which forms MQW 7 includes a maximum width 49 which may range from 0.5 to 2 μm according to various exemplary embodiments and may advantageously be 1 μm in one exemplary embodiment. MQW 7 includes beveled end 13 which produces angled face 47. Together, the taper of beveled end 13, and the decreasing thickness of waveguide 15 towards emitting facet 41, produces a low loss mode transfer and narrow far field. SSC laser 10 of the present invention is therefore suitable for use within a transmit optical subassembly or a transceiver or other optical subassembly of reduced size and increased functionality because an isolator or lens is not needed and SSC laser 10 does not require cooling.

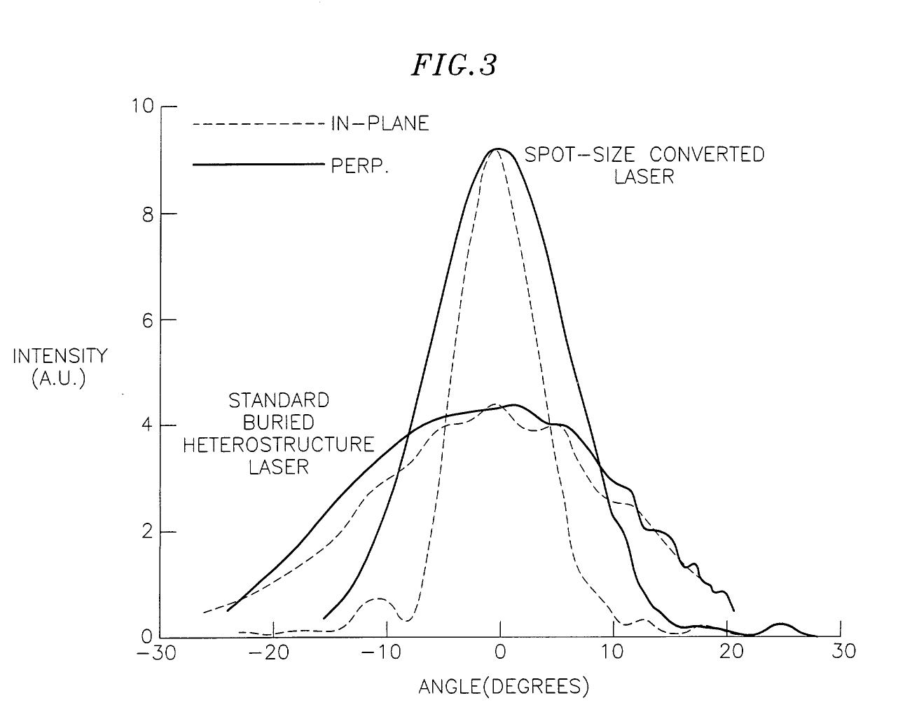

FIG. 3 is a graph showing the far fields achieved by exemplary SSC (spot-size converted) laser 10 compared to standard buried heterostructure (BH) lasers. It can be seen that the far field is desirably reduced considerably for the spot-size converted laser of the present invention, compared to conventional lasers. Far fields of 10×10 to 15×15 are achievable according to the SSC laser of the present invention, compared to BH laser far fields of approximately 30×30. The advantageously reduced far field allows for optical coupling by passive alignment to an optical transmission medium such as an optical fiber, high optical coupling efficiency, and high quality optical data signal transmission that can withstand considerable reflection, even when coupled without a lens or isolator.

Spot-size-converted laser 10 of the present invention provides the advantage that it can be coupled to an optical transmission medium such as an optical fiber using passive alignment to provide sufficiently high optical coupling. Another advantage of SSC laser 10 of the present invention is that it can be used with a low optical coupling efficiency advantageously chosen to minimize reflection from the optical fiber to which it is coupled, such that the laser can provide an optical signal to the optical fiber or other optical transmission medium to enable transmission up to 15 kilometers within industry standard specifications, including low optical path power penalties, without the use of an isolator or lens to couple the laser to the optical transmission medium.

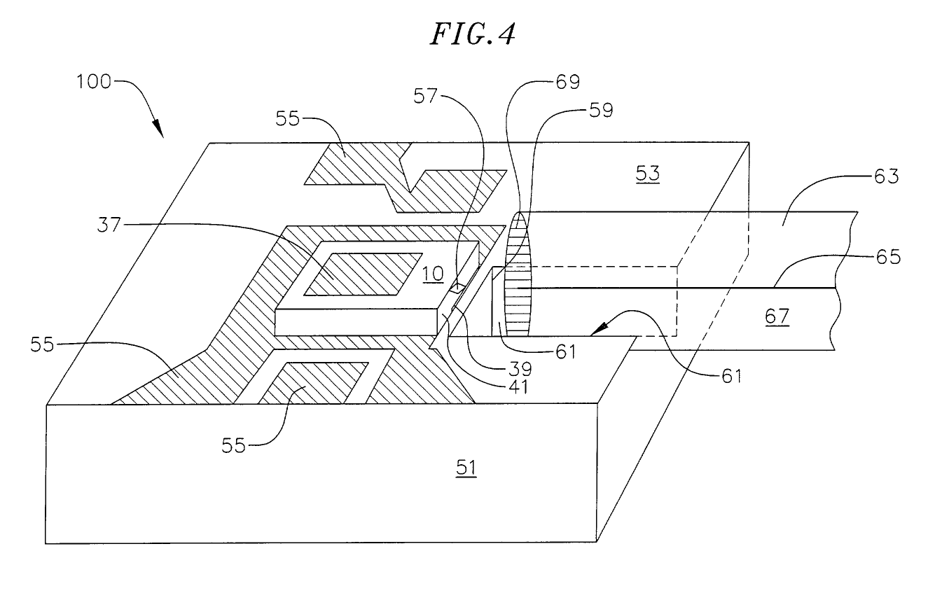

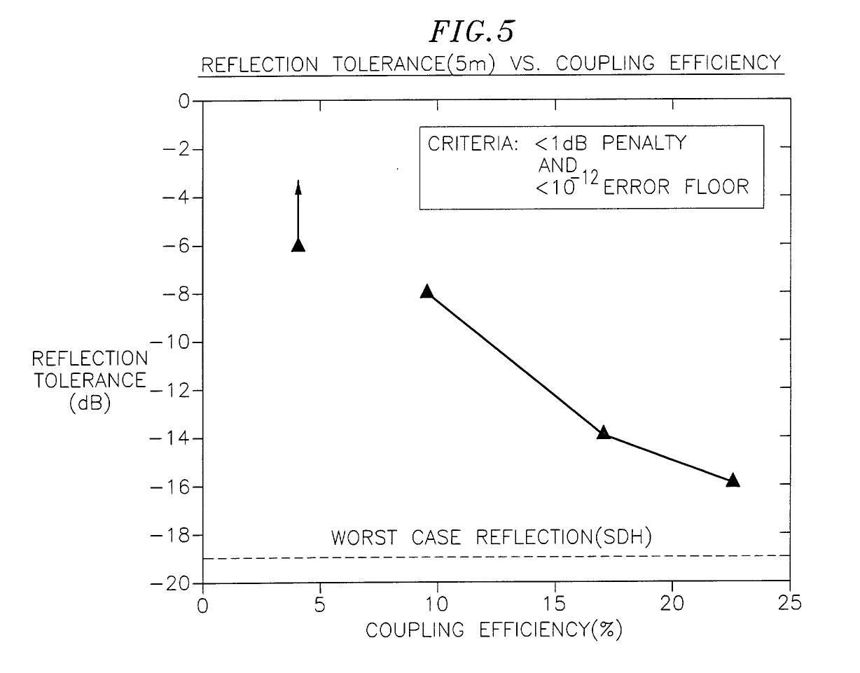

FIG. 4 is a perspective view showing SSC laser 10 formed on submount substrate 51 of TOSA 100. SSC laser 10 may be affixed to submount substrate 51 using various suitable techniques. TOSA 100 will include additional components among which may be receiver components in various exemplary embodiments. SSC laser 10 operates over a −40° C. to 85° C. temperature range and does not require cooling. This results in increased miniaturization of TOSA 100 as a cooling medium is not required. In one embodiment, the device operates at 65° C. or within the range of 65° C. to 85° C. SSC laser 10 is capable of providing an optical signal having a data rate as high as 10 Gbps along an optical transmission medium such as an optical fiber and in one exemplary embodiment may provide a data rate of 2.5 Gbps. SSC laser 10 may be produced to provide light having various wavelengths. In one embodiment, SSC laser 10 may be a DFB laser tuned to provide light having a wavelength of about 1.3 or 1.55 microns. Submount substrate 51 may be formed of silicon or other suitable materials and includes surface 53 which includes metalization 55. Metalization 55 may provide contact to the subjacent one of P-contact metal 37 and N-contact metal 39 shown in FIG. 1. In the exemplary embodiment illustrated in FIG. 4, SSC laser 10 is oriented such that P-contact metal 37 is oriented upward and N-contact metal 39 is underneath and in contact with metalization 55, but the relative positioning may be reversed according to other exemplary embodiments. Submount substrate 51 includes groove 59 formed therein and including surfaces 61. Groove 59 may be formed using various suitable conventional means. In an exemplary embodiment, groove 59 is V-shaped, but other shapes may be used in other exemplary embodiments. Groove 59 is formed with precision such that, once SSC laser 10 is mounted on submount substrate 51, an optical transmission medium such as an optical fiber may be passively aligned to SSC laser 10, which is coupled to submount substrate 51, such that an acceptable optical coupling efficiency is achieved between SSC laser 10 and the optical transmission medium. Groove 59 may be formed and SSC laser 10 may be joined to submount substrate 51 such that an alignment tolerance of about 1 micron is achieved between the SSC laser 10 and the optical transmission medium.

In the illustrated embodiment, the optical transmission medium is optical fiber 63, including fiber core 65. Optical fiber 63 also includes outer surface 67 and end facet 69, which may be a cleaved surface in an exemplary embodiment. In one exemplary embodiment, optical fiber 63 may be a standard single mode fiber. Cleaved end facet 69 faces the emitting end, facet 41 of SSC laser 10. When SSC laser 10 is powered by electrical connection (not shown), light is emitted substantially at portion 57 of end facet 41 and coupled into fiber core 65. The passive alignment between optical fiber 63 and the light emitted at portion 57 of end facet 41 of SSC laser 10 is achieved by positioning optical fiber 63 within groove 59. Otherwise stated, groove 59 receives optical fiber 63 such that portions of outer surface 67 form a conterminous boundary with both surfaces 61 of groove 59. End facet 69 of optical fiber 63 may be formed by cleaving or other means and may be substantially parallel to end facet 41 or end facet 69 may be a substantially planar surface that is angled with respect to end facet 41.

According to another exemplary embodiment, the optical fiber or other optical transmission medium may be terminally encased within a ferrule or other member. Groove 59 formed in submount substrate 51 may be correspondingly sized to receive the ferrule or other member containing the optical transmission medium such that the optical transmission medium will be passively aligned to SSC laser 10 to include a suitable coupling efficiency when the ferrule or other member is received within groove 59. According to either of the exemplary embodiments, various conventional means may be used to secure the optical transmission medium within groove 61. According to either of the aforementioned exemplary embodiments, a time and cost savings is achieved because an active alignment procedure is not required.

It is an aspect of the present invention that the mounted SSC laser 10 and passively aligned optical fiber 63 achieve a suitably high coupling efficiency without a lens to focus the laser, or an isolator. In various exemplary embodiments, coupling efficiencies greater than 25% can be achieved. A device far field of approximately 15×10, achievable by SSC laser 10, provides a coupling efficiency of greater than 25%. In another exemplary embodiment, a coupling efficiency within the range of 30-50% is achieved.

It is another aspect of the present invention that SSC laser 10, notably without a lens or isolator, provides sufficient resistance to optical reflection to enable high speed data transmission up to 15 kilometers at a reduced coupling efficiency, with optical path power penalties that satisfy and exceed the various aforementioned industry-standard specifications. Such high quality data transmission is achievable with the reduced coupling efficiencies advantageously used to minimize reflection from the optical transmission medium. Reflection is defined as the power ratio directed back into the TOSA along the optical transmission medium such as an optical fiber. The optical transmission medium is also coupled to a receiver (not shown). Either or both of the receiver and the optical transmission medium itself, may contribute to the reflection directed along the optical transmission medium and back into the TOSA.

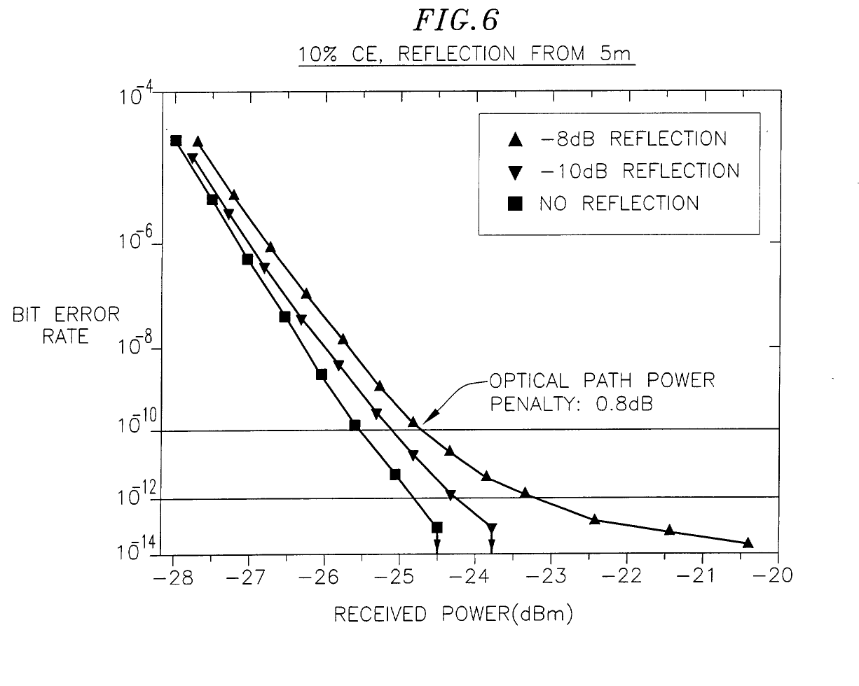

FIG. 5 is a graph showing reflection tolerance in decibels (dB) versus coupling efficiency in percentage. FIG. 5 is an exemplary embodiment that covers 5 meter transmission. According to the exemplary embodiment in which the criteria is to maintain less than a 1 dB optical path power penalty and less than a 10⁻¹² error floor, FIG. 5 shows that, as the reflection tolerance increases (approaches 0, which represents 100% reflection), coupling efficiency decreases. This demonstrates that a lower coupling efficiency is advantageously used to provide an increased reflection tolerance. Stated alternatively, a lower coupling efficiency between the laser and optical transmission medium reduces sensitivity to reflection. It is an advantage of the present invention that, with a coupling efficiency of about 10% to provide an acceptably high reflection tolerance, the TOSA of the present invention delivers an acceptably high quality data signal. While an even lower coupling efficiency may further reduce sensitivity to reflection, a minimum coupling efficiency is required for acceptable data transmission.

SSC laser 10 of the present invention is capable of producing an output power between −5 dBm and 0 dBm. For typical 15 km transmission lengths, desired power is approximately −3 dBm which typically utilizes a coupling efficiency of approximately 10%. Such is exemplary only, and other power levels using different coupling efficiencies may be used in other exemplary embodiments.

The SDH/SONET standards (STM-16/OC-48) for 15 kilometer transmission, require an optical path (reflection/dispersion) power penalty of less than 1 dB for reflection up to −19 dB. This back reflection from the optical fiber may be due to the optical fiber itself (up to −24 dB) and/or the receiver coupled to the optical fiber (up to −27 dB). The optical path power penalty generally is the additional power required to overcome system reflectance and dispersion, etc., and maintain a given bit error ratio achievable by the same system without such influences. In the present example, the optical path power penalty is the penalty produced due to system reflection, and not considering any dispersion effects. The TOSA of the present invention exceeds the requirements of the SDH/SONET standards because it maintains a maximum optical path power penalty of 1 dB at a bit error rate of 10⁻¹⁰ with system reflection up to 14 dB, higher than the allowable −19 dB maximum system reflection of ITU-T SDH standard G.957 STM-16 S-16.1, for example (2.48832 Mb/s, short reach application using 1.3 μm directly modulated lasers at up to 15 km). In one embodiment, the 1 dB optical path power penalty is maintained with system reflection of −8.5 dB. In another embodiment, the passively aligned TOSA and distributed feedback SSC laser of the present invention provide a data signal along an optical transmission with the above characteristics using a coupling efficiency of about 10% for transmission up to 15 km and at a data rate in the range of 1-2.5 Gbps and a wavelength of 1.3 microns, without a lens or isolator. In summary, the TOSA arrangement of the present invention is robust with respect to high system reflections and meets and exceeds 2.5 Gbps SDH/SONET standards (STM-16/OC-48) for 15 km transmission and at a bit error ratio of 10⁻¹⁰, and SDH/SONET standard specifications (STM-48/OC-192) at 10 Gbps. Furthermore, in various embodiments, the TOSA arrangement of the present invention meets and exceeds the aforementioned Gigabit Ethernet, 10 Gigabit Ethernet and Fiber Channel specifications.

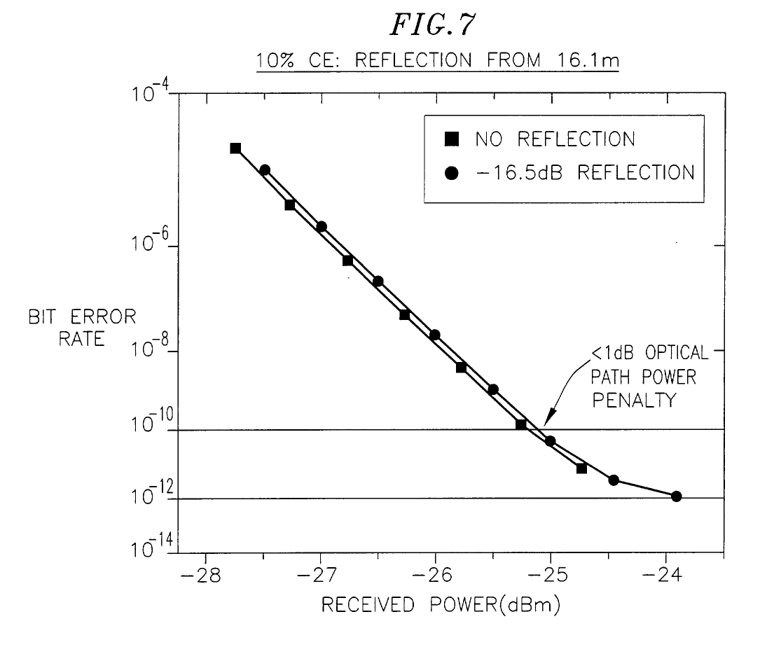

FIG. 6 is a graph showing bit error rate versus received power in dBm for an exemplary TOSA of the present invention including the passively aligned SSC laser coupled to an optical transmission medium without a lens or isolator. FIG. 6 covers an exemplary embodiment of 5 meter transmission with a 10% coupling efficiency. It can be seen that for various exemplary reflection levels, a bit error rate of 10⁻¹⁰ is achievable with the specified optical path power penalty of 1 dB or less. FIG. 6 illustrates that to maintain a bit error rate of 10⁻¹⁰ with a reflection of −8 dB, a 0.8 dB optical path power penalty results, i.e. the difference between the received power of approximately −24.6 dBm to maintain a 10⁻¹⁰ bit error rate with −8 dB reflection and the received power of approximately −25.4 dBm for the bit error rate of 10⁻¹⁰ without reflection. Various output powers in the −5 dBm to 0 dBm range may be provided by the SSC laser in various exemplary embodiments, to provide the indicated received powers.

FIG. 7 is a graph showing bit error rate versus received power in dBm for an exemplary TOSA of the present invention including the passively aligned SSC laser coupled to an optical transmission medium without a lens or isolator. The graph in FIG. 7 covers the exemplary embodiment for 16.1 km transmission and using a 10% coupling efficiency. FIG. 7 shows that, for a −16.5 dB reflection, a bit error rate of 10⁻¹⁰ is achievable within the maximum 1 dB optical path power penalty.

The preceding graphs of FIGS. 6 and 7 are intended to be exemplary and explanatory and are used to illustrate the fundamental concept of the present invention that, according to various exemplary embodiments, the passively-aligned TOSA of the present invention, including the spot-size-converted semiconductor laser of the present invention coupled to an optical fiber or the like without a lens or isolator, can provide a data signal with a bit error ratio of 10⁻¹⁰ or less and enable 1-10 Gbps transmission within the optical path power penalty specified by various SDH/SONET standards, for various system reflection values.

The preceding merely illustrates the principles of the invention. It will thus be appreciated that those skilled in the art will be able to devise various arrangements which, although not explicitly described or shown herein, embody the principles of the invention and are included within its scope and spirit. Furthermore, all examples and conditional language recited herein are principally intended expressly to be only for pedagogical purposes and to aid in understanding the principles of the invention and the concepts contributed by the inventors to furthering the art, and are to be construed as being without limitation to such specifically recited examples and conditions. Moreover, all statements herein reciting principles, aspects, and embodiments of the invention, as well as specific examples thereof, are intended to encompass both structural and the functional equivalents thereof. Additionally, it is intended that such equivalents include both currently known equivalents and equivalents developed in the future, i.e., any elements developed that perform the same function, regardless of structure. The scope of the present invention, therefore, is not intended to be limited to the exemplary embodiments shown and described herein. Rather, the scope and spirit of the present invention is embodied by the appended claims.

What is claimed is:

1. A TOSA (transmit optical subassembly) comprising a spot-size-converted semiconductor laser directly coupled to an optical transmission medium that provides an optical data signal having a bit error rate no greater than 10⁻¹⁰ and a data rate within the range of 1 Gbps to 10 Gbps.

2. The TOSA as in claim 1, wherein said TOSA is further characterized by said optical data signal having a maximum 1 dB optical path power penalty with a maximum −19 dB back reflection, over said optical transmission medium having a length as great as 15 km.

3. The TOSA as in claim 1, in which said laser is characterized by the capability to withstand as much as −19 dB reflection and produce said optical data signal that satisfies ITU-T G.957 STM-16 S-16.1 specifications for 15 km transmission.

4. The TOSA as in claim 1, wherein said optical transmission medium is an optical fiber having a length of at least 10 km, and a beveled end facing said laser.

5. The TOSA as in claim 1, in which said TOSA is further characterized by said laser providing said optical data signal that satisfies at least one of SONET specifications OC-48 and OC-192 and SDH specifications STM-16 and STM-48.

6. The TOSA as in claim 1, in which said TOSA is further characterized by said laser providing said optical data signal that satisfies at least one of Gigabit Ethernet (IEEE 802.3z 1000BASE-LX), 10 Gigabit Ethernet (IEEE 802.ae 10GBASE-C), 10 Gigabit Ethernet (IEEE 802.ae 10GBASE-E) and Fiber Channel (ANSI X3T11) standard specifications.

7. The TOSA as in claim 1, wherein said laser provides an optical power within the range of −5 dBm to 0 dBm.

8. The TOSA as in claim 1, wherein said laser comprises one of a Fabry-Perot laser and a distributed feedback laser.

9. The TOSA as in claim 1, in which said laser emits light having a far field no greater than 15×15.

10. The TOSA as in claim 1, in which said laser emits light having a wavelength of one of about 1.3 microns and about 1.55 microns.

11. The TOSA as in claim 1, in which said laser is affixed to a submount including a groove therein, said optical transmission medium received within said groove and contacting surfaces of said groove and thereby passively aligned to said laser.

12. The TOSA as in claim 11, wherein groove is a V-shaped groove and an outer surface of said optical transmission medium contacts both surfaces of said V-shaped groove.

13. The TOSA as in claim 11, in which said optical transmission medium is affixed to a member disposed within and contacting surfaces of, said groove.

14. The TOSA as in claim 1, in which said laser is an edge emitting distributed feedback laser formed over a substrate and includes a first end facet optically coupled to said optical transmission medium and coated with an antireflective coating and an opposed end facet coated with a reflective coating.

15. The TOSA as in claim 1, in which said laser includes an expander region and an active region including quantum well layers comprising a stack of a repeating sequence of films disposed over a substrate and forming a mesa having a beveled end facing said expander region, such that light produced in said quantum well layers is propagated in said expander region by means of a waveguide, said waveguide including a first thickness in said active region and a second thickness in portions of said expander region and a taper therebetween, said first thickness being greater than said second thickness.

16. The TOSA as in claim 1, in which said laser includes an active region and an expander region each formed over a substrate and further comprising a grating structure formed beneath quantum well layers of said active region.

17. The TOSA as in claim16, in which the grating structure includes one of a periodic loss and periodic gain structure.

18. The TOSA as in claim 1, in which said laser includes a spot size of about 1 micron in an active region thereof and further includes an expander section that expands said spot size to about 4 microns.

19. The TOSA as in claim 1, in which said laser is an uncooled laser.

20. The TOSA as in claim 1, in which said TOSA further includes optical receiver components therein.

21. The TOSA as in claim 1, in which said TOSA further includes multiplexing and demultiplexing components therein.

22. A TOSA (transmit optical subassembly) comprising a spot-size-converted semiconductor laser directly coupled to an optical transmission medium that provides an optical data signal that satisfies at least one of ITU-T SDH STM-16 standard specifications and SONET OC-48 standard specifications.

23. A method for transmitting an optical signal, comprising:
providing a spot-size-converted semiconductor laser coupled to a submount, said submount including a groove therein for passively aligning an optical transmission medium to said laser;
providing an optical fiber having an end capable of being received within said groove;
passively aligning said optical fiber to said laser without a lens and without an isolator, by positioning said end of said optical fiber in said groove such that said laser is capable of providing an optical data signal along said optical fiber having a bit error rate less than 10⁻¹⁰ and a data speed of 1-10 Gbps; and
causing said laser to emit light thereby providing said optical data signal.

24. The method as in claim 23, in which said causing comprises causing said laser to emit light having a power within the range of −5 dBm to 0 dBm and a wavelength of one of about 1.3 microns and about 1.55 microns.

25. The method as in claim 23, in which said causing includes causing said laser to emit an optical data signal that satisfies at least one of ITU-T SDH STM-16 and STM-48 standard specifications, and SONET OC-48 and OC-192 standard specifications.

26. The method as in claim 23, in which said passively aligning and said causing produce said optical signal having an optical path power penalty no greater than 1 dB over a 15 km optical transmission medium with a back reflection as great as −14 dB.

27. A method for transmitting an optical signal, comprising:
providing a spot-size-converted semiconductor laser coupled to a submount, said submount including a v-shaped groove therein for passively aligning an optical transmission medium to said laser;
providing an optical fiber having an end capable of being received within said groove;
passively aligning said optical fiber to said laser without a lens or isolator by positioning said end of said optical fiber in said groove such that external portions of said optical fiber contact surfaces of said groove; and
causing said laser to emit light and achieving at least 25% coupling efficiency between said laser and said optical fiber.
